(19) United States
(12) Patent Application Publication
(10) Pub. No.: US 2021/0325483 A1
(43) Pub. Date: Oct. 21, 2021

(54) Sensor Device and Sensor Assembly For Measuring The Rotational Position of an Element

(71) Applicants: TE Connectivity Belgium BVBA, Oostkamp (BE); TE Connectivity Germany GmbH, Bensheim (DE)

(72) Inventors: Tom Ocket, Oostkamp (BE); Tobias Becker, Speyer (DE); Moritz Harz, Speyer (DE)

(73) Assignees: TE Connectivity Belgium BVBA, Oostkamp (BE); TE Connectivity Germany GmbH, Bensheim (DE)

(21) Appl. No.: 17/231,427

(22) Filed: Apr. 15, 2021

(30) Foreign Application Priority Data
Apr. 15, 2020 (EP) 20169626

(51) Int. Cl. G01R 33/02; G01D 5/22; G01D 5/245

(52) U.S. Cl. CPC G01R 33/02; G01D 5/2454; G01D 5/22

(57) ABSTRACT

A sensor device arranged at a stator measures a rotational position of an encoder member arranged at a rotor. The encoder member is rotatable about an axis of rotation. The sensor device includes a sender member arranged at the stator and emitting a magnetic field and a receiving member receiving the magnetic field. The receiving member has a plurality of adjacent sensor areas arranged along a circumferential direction about the axis of rotation in a plane opposing the encoder member.

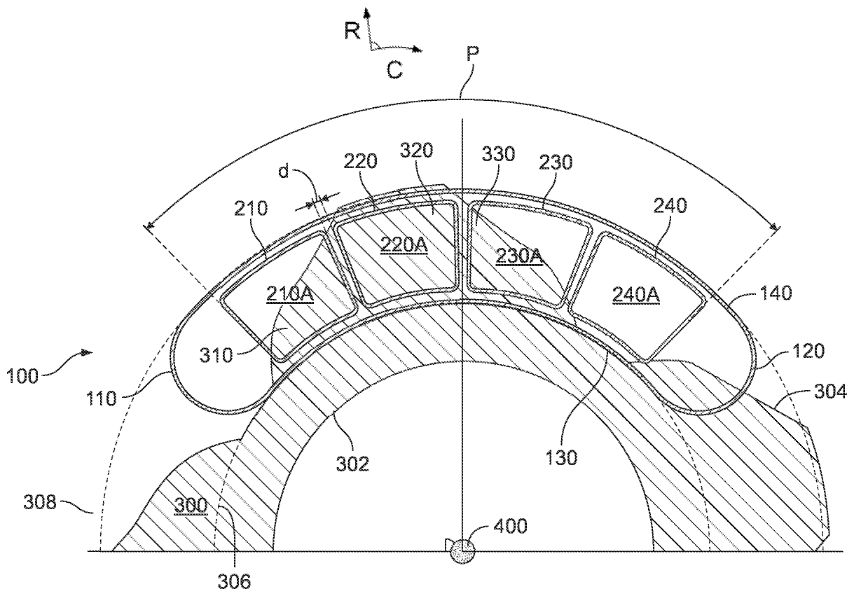

### CROSS-REFERENCE TO RELATED APPLICATION

This application claims the benefit of the filing date under 35 U.S.C. § 119(a)-(d) of European Patent Application No. 20169626, filed on Apr. 15, 2020.

### FIELD OF THE INVENTION

The present invention relates to a sensor device and, more particularly, to a sensor device for measuring the rotational position of an element that is rotatable about an axis of rotation.

### BACKGROUND

Sensor devices for measuring a rotational position have at least one sender member for emitting a magnetic field and a plurality of receiving members for receiving the magnetic field. An encoder member is made of a conductive material, having a shape with a periodic structure in a circumferential direction. The receiving member is an inductive component. Thus, the rotational position of the encoder member can be determined.

In another exemplary sensor device, a sender member is arranged at a stator. The receiving members are arranged at the stator to sense the magnetic field generated by the sender member. In more detail, a conductor forms each receiving member. Each conductor delimits a plurality of surrounded areas, wherein the areas are at least partly overlapping. Further, the encoder member is made of a conductive material so that it influences the magnetic field of the sender member as an Eddy current is induced in the encoder member. In other words, the magnetic field generated by the sender member is disturbed depending on the angular position of the encoder member. Thus, the rotational position of the encoder member can be determined.

The aforementioned sensor devices, however, are often imprecise. For example, a sensor device arranged in an annular ring segment causes harmonics in the angular error, because the magnetic flux is different at the ends of the sensor relative to a central part of the sensor.

### SUMMARY

A sensor device arranged at a stator measures a rotational position of an encoder member arranged at a rotor. The encoder member is rotatable about an axis of rotation. The sensor device includes a sender member arranged at the stator and emitting a magnetic field and a receiving member receiving the magnetic field. The receiving member has a plurality of adjacent sensor areas arranged along a circumferential direction about the axis of rotation in a plane opposing the encoder member.

### BRIEF DESCRIPTION OF THE DRAWINGS

The invention will now be described by way of example with reference to the accompanying Figures, of which:

The Figure is a schematic sectional side view of a sensor system according to an embodiment.

### DETAILED DESCRIPTION OF THE EMBODIMENT(S)

The invention will now be described in detail, in an exemplary manner using embodiments and with reference to the drawings. The described embodiments are only possible configurations in which, however, the individual features as described herein can be provided independently of one another or can be omitted.

An assembly according to an embodiment, as shown in the Figure, comprises a sensor device for measuring the rotational position of an encoder member 300 that is rotatable about an axis of rotation 400. The sensor device has a sender member 100 for emitting a magnetic field and a receiving member for receiving the magnetic field. The sensor device is arranged at a stator and the encoder member 300 is arranged at a rotor. A polar coordinate system is used in which each point on a plane is determined by a distance from a pole, namely the axis of rotation. The distance from the pole is measured in the radial direction and the angle is measured in the circumferential direction about the pole.

The sender member 100 follows the shape of an annular ring segment, as shown in the Figure. The sender member 100 has radial sections 110 and 120 and segment sections 130 and 140. The radial sections 110, 120 interconnect the opposing segment sections 130, 140 thereby forming a closed loop. As a matter of presentation, in the Figure the conductors that form the sections 110, 120, 130, 140 are closed, but in fact at one side a loop is open and connected to an electronic circuitry such as an integrated chip that is measuring those signals. Furthermore, the closed loop can be spiral coil.

The sender member 100 has a conductive path that forms a coil, in particular a spiral coil on the arcuate carrier, which is embodied as a PCB. The coil of the sender member 100 can be planar. When running a current through the sender member 100, a magnetic field results which is then disturbed by the encoder member 300 and received by the receiving member. Depending on whether the current of the sender member 100 runs in one direction or the other, for example clockwise or counterclockwise in the sender member 100, the magnetic field is directed in one direction or the other. In an embodiment, the magnetic field is an alternating material field achieved by applying an alternating current at the sender member 100. In general, the sender member 100 is in shape an annular ring segment. Thus, the sensor device can be fabricated in a particular compact design.

As shown in the Figure, the radial sections 110, 120 are formed as curved sections. However, the radial sections 110, 120 can be alternatively formed as straight sections. Curved sections may provide a more homogeneous magnetic field at the receiving element. Straight sections may enable a more compact design of the sensor device.

The receiving member according to the embodiment shown in the Figure has four adjacent sensor areas 210A, 220A, 230A, and 240A. As used herein, adjacent means that the four areas are arranged side by side. The individual areas do not overlap; the individual areas are spaced apart from each other by a predetermined nonzero distance. Alternatively, the receiving member may comprise more than four adjacent sensor areas. For example, the sensor may consist of (j×4) sensor areas, where j is an integer greater than 1.

As shown in the Figure, conductors 210, 220, 230, and 240 delimit the sensor areas 210A, 220A, 230A, and 240A, respectively. The term delimit can here be understood as circumscribe, surround and/or substantially enclose. Each conductor 210, 220, 230, 240 defines a closed loop. In an embodiment, each loop is a turn of wire or a coil. As a matter of presentation, in the Figure the conductors 210, 220, 230, and 240 are closed, but in fact at one side each loop is open and connected to an electronic circuitry that is evaluating those signals. According to an alternative embodiment, the closed loops surrounding the sensor areas 210A, 220A, 230A, and 240A are connected with traces on a printed circuit board (PCB). In an embodiment, conductor 210 is connected to conductor 230 and conductor 220 is connected to conductor 240. In an embodiment, abutting coils of the four coils are wound in opposite direction.

In the embodiment shown in the Figure, the sensor areas 210A, 220A, 230A, and 240A are each shaped as an annular ring segment. In particular, each sensor area 210A, 220A, 230A, and 240A is delimited in radial direction by segment sections having substantially the same shape as the segment sections 130, 140 of the sender element 100. Substantially the same shape means that the segment sections are parallel in polar coordinates. Such a configuration allows maximizing the area covered by the sensor areas 210A, 220A, 230A, and 240A within the annular ring surrounded by the sender member 100. The shape of an annular ring segment can be approximated as the shape of trapezoid.

In an embodiment, the sections of each of the conductors 210, 220, 230, 240 that define the sensor areas 210A, 220A, 230A, and 240A comprise mainly or only curved sections in the circumferential direction and only or mainly straight sections in the radial direction. This can further improve the signal quality as the sensor area is maximized. Notably, additional straight sections can however be present in other parts of the conductors 210, 220, 230, 240. For example, parts of the conductors 210, 220, 230, 240 that do not surround the areas, e.g. connect the loop, and/or do not bound/limit the sensor areas 210A, 220A, 230A, and 240A, e.g. contacting sections and or a terminal or solder part.

According to the example disclosed in the Figure, the sensor areas 210A, 220A, 230A, and 240A are arranged adjacent in the circumferential direction C around the axis of rotation 400. In particular, abutting sensor areas 210A, 220A, 230A, and 240A are spaced apart by the distance d in the circumferential direction C. Such a configuration of not overlapping sensor areas 210A, 220A, 230A, and 240A enable an alternative solution to the rotary sensors with intersecting loops. Each area 210A, 220A, 230A, and 240A has substantially the same distance to the axis of rotation 400, but each area 210A, 220A, 230A, and 240A has a different angular component. In other words, the four areas 210A, 220A, 230A, and 240A are arranged within one annular ring.

According to the example disclosed in the Figure, four sensor areas 210A, 220A, 230A, and 240A are arranged within an annular ring segment having period P along the circumferential direction C about the axis of rotation 400. Furthermore, all of the sensor areas 210A, 220A, 230A, and 240A have the same or identical shape. I.e., sensor areas 210A, 220A, 230A, and 240A are congruent when shifted along the circumferential direction C. In the embodiment shown in the Figure, each of the four sensor areas 210A, 220A, 230A, and 240A is arranged within an annular ring segment having a quarter of the period P. Having a period P means that the annular ring segment has substantially the period P along the circumferential direction C. In particular, a period P that deviates only by ΔP is intended to be seen as an annular ring segment having substantially the period P. In particular, ΔP is less than half the period P. Not shown in the Figure is that the shape of only a part of the areas 210A, 220A, 230A, and 240A may deviate by use of a correction term. Such a configuration enables to correct for edge effects.

An annular ring segment is an angular sector of an annular ring, which is “cut off” from the rest of the annular ring. The segment is defined only in an angle Θ on the annular ring, wherein the angle Θ is smaller than the full mechanical resolution of 360° of the sensor. In more detail, the sensor areas are arranged within an angle Θ around the circumferential direction C about the pole. Mechanically, this annular ring segment has the nonzero length of the constant P that defines the fundamental period. Electrically, the period P corresponds to 2 Pi or 360 degrees. Herein, the term angular resolution refers to the electrical resolution.

A plurality of n abutting annular ring segments, wherein n is an integer greater than 1, form mechanically a complete annular ring. Notably, a plurality of n elements on the rotor alternatively allow a full mechanical resolution. Such an annular ring segment enables to save costs and assembly space. Advantageously, a plurality of n encoder elements with period P are defined on the rotor, n being an integer inverse proportional to Θ.

The encoder member 300 in the embodiment of the Figure is attached to the axis of rotation 400 such that it rotates with the axis of rotation 400. In this example, four flaps (the Figure shows one flap completely and two flaps partly) are connected to a ring section and protrude sideways away from the ring section perpendicular to the axis of rotation 400. An inner radius 302 and a ring radius 306, indicated by the dashed line, border the ring section of the encoder member 300. The flaps are arranged between the ring radius 306 and an outer encoder radius 308, indicated by a dashed line.

The encoder member 300 is arranged between the inner radius 302 and an outer shape 304. The encoder element 300 comprises a conductive element in the structure arranged between the outer shape 304 and the outer ring radius 306. For example, the conductive element is a metal or a conductive carrier like copper on the PCB or a conductive ink on a plastic disk.

In the Figure, the outer ring radius 306 is the diameter of the inner segment section 130 and the diameter from where the outer shape 304 starts. Similarly, outer encoder radius 308 is the diameter of the outer segment section 140 and the diameter that radially delimits the outer shape 304. In an embodiment, the shape 304 starts at a diameter less than the outer ring radius 306, and ends at a diameter larger that the outer encoder radius 308.

The encoder member 300 consists of n segments, n being an integer inverse proportional to the period P. In particular, in the Figure, three of the four segments are at least partly shown. Each segment consists of m adjacent parts, m being an integer proportional to the number of sensor areas 210A, 220A, 230A, and 240A. In the arrangement shown in the Figure, each flap is formed by a first part 310 opposing the sensor area 210A, a second part 320 opposing the sensor area 220A, and a third part 330 opposing the sensor area 230A. A fourth part is defined by the void opposing sensor area 240A. In other words, the fourth part is defined where the ring radius 306 is equal to the outer shape 304 of the encoder element.

The encoder member 300 has a structure periodically changing with a period P along a circumferential direction C about the axis of rotation 400. In an embodiment, the structure is based on a trigonometric function in shape. For example, the structure may be composed of a plurality of trigonometric functions. Composed means that for example a plurality of different trigonometric functions are combined by a mathematical operation. Such a configuration allows a highly efficient evaluation or calculation of the position of the encoder element 300. Generally, other configuration may be used which enable an unambiguous relationship between the change of the signal caused by the change area of encoder element 300 opposing the sensor area. In an embodiment, the structure covers a half of the period P in circumferential direction C.

The encoder member 300 forms partly the first part 310, wherein the outer shape 304 of the encoder is changing in the circumferential direction C, namely increasing in a clockwise direction, from the ring radius 306 to the outer radius 308. In particular, the outer shape 304 limiting the first part 310 is curved. For example, as shown in the Figure, the shape 304 follows a function that is based on a composition of trigonometric functions. Consequently, the effects from the Eddy current induced in the first part 310 can be optimized with respect to the arrangement of the sender member 100 and the receiving member.

Further, the encoder member 300 forms partly the second part 320, wherein the outer shape 304 of the encoder is constant in the circumferential direction C following substantially the outer radius 308. In particular, the outer shape 304 is larger than the outer radius 308 of segment sections of the sensor areas 210A, 220A, 230A, and 240A. Consequently, the effects from the Eddy current induced in second part 320 is maximized.

The encoder member 300 forms partly the third part 330, wherein the outer shape 304 of the encoder is changing in the circumferential direction C, namely decreasing in a clockwise direction, from the outer radius 308 to the ring radius 306. In particular, the outer shape 304 limiting the third part 330 is curved. For example, as shown in the Figure, the shape 304 follows a trigonometric function. Consequently, the effect from the Eddy current induced in the third part 330 can be optimized with respect to the arrangement of the sender member 100 and the receiving member. In an embodiment, the third part 330 is mirror symmetric to the first part 310 with respect to a symmetry axis that is directed in the radial direction R, wherein the symmetry axis passes through the center of the second part 320. Consequently, the same effect from the Eddy current is generated in the first part 310 and the third part 330 for the position shown in the Figure.

The encoder member 300 comprises the void, wherein the outer shape 304 of the encoder is constant in the circumferential direction C following substantially the ring radius 302. In particular, the outer shape 304 is less in radius than the inner radius of the segment sections of the sensor areas 210A, 220A, 230A, and 240A. Consequently, no effect from Eddy current is induced in a part of the encoder member 300 forming the void.

To keep the sensor device compact, the sender member 100 lies substantially in the plane opposing the encoder member 300. The plane can be perpendicular to the axis of rotation 400. Such a plane has to be understood as a substantially flat object where one dimension is much smaller than the other two dimensions. Parts of the sensor device can for example be located on a front side of a PCB and other parts can be located on a backside of the PCB. In such an embodiment, the sensor device would still lie substantially in a plane.

Now, with reference to the Figure, a way of operating the sensor assembly is described. In the configuration shown in the Figure, four voltage values are sensed by the adjacent sensor areas. In particular, the voltage V4 is sensed by sensing area 240A. V4 is a maximum value of the voltage sensed by sensing area 240A as no Eddy current is induced in the void. Further, the voltage V2 is sensed by sensing area 220A. V2 is a minimum value of the voltage sensed by sensing area 220A as a maximum Eddy current is induced in the second part 320. Further, the voltage V1 is sensed by sensing area 210A. V1 is an intermediate value of the voltage sensed by sensing area 210A as an intermediate Eddy current is induced in the first part 310. Intermediate means a value between the maximum value and a minimum value. Finally, the voltage V3 is sensed by sensing area 230A. V3 is an intermediate value of the voltage sensed by sensing area 230A as an intermediate Eddy current is induced in the third part 310. By using the four voltage values V1 to V4, an absolute position of the encoder member 300 can be determined. In particular, the voltage needs to be amplified and rectified only, which can be done analog, and makes it easier to achieve a higher functional safety level.

By rotating the encoder member 300, all four voltage values are changing, and thus, a position dependent signal is generated. In the embodiment shown in the Figure, the amount of the voltage value V1 equals the amount of voltage value V3, due to the symmetry of the arrangement. However, edge effects, e.g. by radial section 110, may cause errors so that the angular resolution deteriorates.

In an embodiment, the sensing areas 210A and 230A are interconnected forming a first receiver or first sensing element for providing a first sensing signal and the sensing areas 220A and 240A are interconnected forming a second receiver or a second sensing element for providing a second sensing signal. Such a configuration allows forming two balanced coil system. In particular, by disturbing the balanced system (with the rotor) leads to voltages in the two receivers. For example, a sine signal is received from the first receiver and a cosine signal is received from the second receiver. Two distinct signals enable an absolute angle measurement within the annular ring segment. I.e. by a comparison of the two distinct signals, e.g. a division operation, the absolute position within the ring segment can be determined. Such a configuration is advantageous in case that the sensor areas are arranged within an annular ring segment having period P.

In an embodiment, a first conductor forms a pair of first loops and a second conductor forms a pair of second loops. Such a configuration allows an economic fabrication of the first sensing element and the second sensing element. In another embodiment, each of the first loops formed by the first conductor is wound in opposite direction. Thus, in the first loops delimiting the first pair of sensor areas a voltage having an opposite sign is induced in each of the first loop. In other words, the pair of first loops wound in opposite direction allows a phase/anti-phase arrangement of the loops. Such a configuration allows a balanced coil system. Each receiver pair has a net zero voltage optimal case. By disturbing the balanced system with the rotor leads to a voltage in the receivers. Similarly, each of the second loops formed by the second conductor is wound in opposite direction. In another embodiment, the first loops and the second loops are arranged alternatively. In other words, the first loops are abutting to the second loops and vice versa.

The configuration shown in the Figure allows modifying the outer shape 304 of the first part 310 and the third part 330. In particular, the shape 304 is curved to compensate for the edge effects. In other words, the geometry of the encoder member 300 is modified to reduce angular errors. Further, the embodiment shown in the Figure additionally allows modifying the width and height of the sender member 100 to compensate for edge effects. Further, the configuration shown in the Figure additionally allows modifying the position of the sensor areas 210A, 220A, 230A, and 240A to compensate for edge effects. Such a configuration increases the flexibility for optimizing the arrangement in order to reduce edge effects.

The sensor device and the sensor assembly of the present invention limit assembly space, reducing the area of the annular ring segment, and provide a higher precision.

What is claimed is:

1. A sensor device arranged at a stator for measuring a rotational position of an encoder member arranged at a rotor, the encoder member is rotatable about an axis of rotation, the sensor device comprising:
a sender member arranged at the stator and emitting a magnetic field; and
a receiving member receiving the magnetic field, the receiving member having a plurality of adjacent sensor areas arranged along a circumferential direction about the axis of rotation in a plane opposing the encoder member.

2. The sensor device of claim 1, wherein the sensor areas are arranged within an annular ring segment having a period along the circumferential direction about the axis of rotation.

3. The sensor device of claim 1, wherein each of the sensor areas is an annular ring segment.

4. The sensor device of claim 1, wherein each of the sensor areas has substantially a same shape.

5. The sensor device of claim 1, wherein a first pair of sensor areas of the sensor areas forms a first sensing element providing a first sensing signal and a second pair of sensor areas forms a second sensing element providing a second sensing signal.

6. The sensor device of claim 1, wherein each of the sensor areas is delimited by a conductor loop.

7. The sensor device of claim 1, wherein the sender member has a coil.

8. The sensor device of claim 1, wherein the sender member surrounds the sensor areas.

9. The sensor device of claim 1, wherein the sender member lies in the plane opposing the encoder member.

10. The sensor device of claim 1, wherein the sender member is a conductive path on a printed circuit board.

11. The sensor device of claim 1, wherein the receiving member is a conductive path on a printed circuit board.

12. A sensor system, comprising:
an encoder member arranged at a rotor and rotatable about an axis of rotation, the encoder member is an electrically conductive material; and
a sensor device arranged at a stator and measuring a rotational position of the encoder member, the sensor device includes a sender member arranged at the stator and emitting a magnetic field and a receiving member receiving the magnetic field, the receiving member having a plurality of adjacent sensor areas arranged along a circumferential direction about the axis of rotation in a plane opposing the encoder member.

13. The sensor system of claim 12, wherein the encoder member has a structure periodically changing with a period along the circumferential direction about the axis of rotation.

14. The sensor system of claim 13, wherein a part of the structure has a shape based on a trigonometric function.

15. The sensor system of claim 14, wherein the part of the structure covers a quarter of the period in the circumferential direction.

16. The sensor system of claim 13, wherein the structure is mirror symmetrical with respect to an axis defined in a radial direction.
